(19) United States
(12) Patent Application Publication
(10) Pub. No.: US 2005/0047107 A1
(43) Pub. Date: Mar. 3, 2005

(54) Compact computer/printer/scanner/webcam all-in-one unit with dual LCD monitors.

(75) Inventor: TSUNG JUNG PAN, Pingtong county (TW)

Correspondence Address: TSUNG JUNG PAN, 33 CHICORY WAY, IRVINE, CA, 92612, US

(73) Assignee: TSUNG JUNG PAN, Pingtong county (TW)

(21) Appl. No.: 10/707,702

(22) Filed: Jan. 6, 2004

(30) Foreign Application Priority Data
Sep. 1, 2003 (TW) 092215809

(51) Int. Cl. H05K 7/02; H05K 7/04

(52) U.S. Cl. 361/807

(57) ABSTRACT

The computer/dual LCD monitors/printer/scanner/webcam all-in-one unit gives users fully capable multi-tasking abilities with the convenience of one unit. Currently, computer users need separate accessories attached to the computer in order to scan, print, or video conference. With the all-in-one unit, however, these tasks can all be accomplished on one compact unit without resorting to separate accessory attachments. In addition to these capabilities, the all-in-one unit is a fully-functional computer with a modem that enables Internet access, a television card that enables television viewing, a DVD ROM drive and dual LCD monitors. All of these functions can be accomplished simultaneously on the one unit; for example, users can check email using one LCD monitor, watch television news using the second LCD monitor, print a document and video conference, all on the same unit. The compact design of the all-in-one unit is also space-saving and portable.

### BACKGROUND OF INVENTION

Most computer accessories such as monitor, printer, scanner, webcam, etc are separate from the computer itself. A fully accessorized computer occupies large spaces and makes portability difficult. This invention minimizes the space a computer and its accessories occupies and eliminates the need for accessory wires and cables, creating a single computer that is easily mobile.

### SUMMARY OF INVENTION

The design reduces the size of the computer by using the PCI extension raise card (part 13) and AGP raise card (part 12). Five internal fans ventilate cool air into the computer and six fans ventilate hot air out of the computer. There are two CD/DVD-ROM racks (part 8 and part 9) that hold two CD/DVD-ROMs (part 29 and part 30) and two hard disk drive racks (part 10 and part 11) that hold two hard disk drives (part 31 and part 32). This invention is a computer, a dual monitor (part 3 and part 4), a printer (part 5), a scanner (part 6), and a webcam (part 7) conveniently compacted into an all-in-one computer.

### BRIEF DESCRIPTION OF DRAWINGS

FIG. 1: CASE A's exploded view.

FIG. 2: CASE A's first CD/DVD-ROM rack, second DVD-ROM rack, first hard disk drive rack, second hard disk drive rack and PCI extension card/PCI extension cable/PCI extension slot already assembled.

FIG. 3: Direction of CASE A's first CD/DVD-ROM, second CD/DVD-ROM and second hard disk drive installation.

FIG. 4: CASE A's first CD/DVD-ROM, second CD/DVD-ROM first hard disk drive, second hard disk drive and Power supply already assembled.

FIG. 5: CASE A's AGP card, PCI card position.

FIG. 6: CASE A's upper panel.

FIG. 7: CASE A's upper panel already assembled.

FIG. 8: CASE A's bottom view.

FIG. 9: CASE A's top view (without upper panel).

FIG. 10: CASE A's front view.

FIG. 11: CASE A's right side view.

FIG. 12: CASE A's rear view.

FIG. 13: CASE A's left side view.

FIG. 14: CASE A's back view.

FIG. 15: First hard disk drive rack's top and side views.

FIG. 16: First hard disk drive rack's 3D view.

FIG. 17: Second hard disk drive rack's top and side views.

FIG. 18: Second hard disk drive rack's 3D view.

FIG. 19: Direction of cold air blowing in and hot air blowing out.

FIG. 20: Dual monitors/printer/scanner/webcam all-in-one computer's exploded view.

FIG. 21: CASE B's front view.

FIG. 22: CASE B's top view.

FIG. 23: CASE B's right side view.

FIG. 24: CASE B's bottom view.

FIG. 25: CASE B's left side view.

FIG. 26: CASE B's back view.

FIG. 27: CASE B's 3D view.

FIG. 28: Dual monitors/printer/scanner/webcam all-in-one computer's 3D view (when in use).

FIG. 29: Dual monitors/printer/scanner/webcam all-in-one computer's 3D view (prepared to scan when LCD monitor B is open).

FIG. 30: Dual monitors/printer/scanner/webcam all-in-one computer's back view.

FIG. 31: Dual monitors/printer/scanner/webcam all-in-one computer's front view (when not in use).

FIG. 32: Dual monitors/printer/scanner/webcam all-in-one computer's top view (when not in use).

FIG. 33: Dual monitors/printer/scanner/webcam all-in-one computer's right side view (when not in use).

FIG. 34: Dual monitors/printer/scanner/webcam all-in-one computer's bottom view (when not in use).

FIG. 35: Dual monitors/printer/scanner/webcam all-in-one computer's left side view (when not in use).

FIG. 36: Dual monitors/printer/scanner/webcam all-in-one computer's back view (when not in use).

FIG. 37: Dual monitors/printer/scanner/webcam all-in-one computer's front view (when in use).

FIG. 38: Dual monitors/printer/scanner/webcam all-in-one computer's top view (when in use).

FIG. 39: Dual monitors/printer/scanner/webcam all-in-one computer's right side view (when in use).

FIG. 40: Dual monitors/printer/scanner/webcam all-in-one computer's bottom view (when in use).

FIG. 41: Dual monitors/printer/scanner/webcam all-in-one computer's left side view (when in use).

FIG. 42: Dual monitors/printer/scanner/webcam all-in-one computer's front view (prepared to scan when LCD monitor B is open).

FIG. 43: Dual monitors/printer/scanner/webcam all-in-one computer's top view (prepared to scan when LCD monitor B is open).

FIG. 44: Dual monitors/printer/scanner/webcam all-in-one computer's right side view (prepared to scan when LCD monitor B is open).

FIG. 45: Dual monitor/printer/scanner/webcam all-in-one computer's bottom view (prepared to scan when LCD monitor B is open).

FIG. 46: Dual monitors/printer/scanner/webcam all-in-one computer's left side view (prepared to scan when LCD monitor B is open)

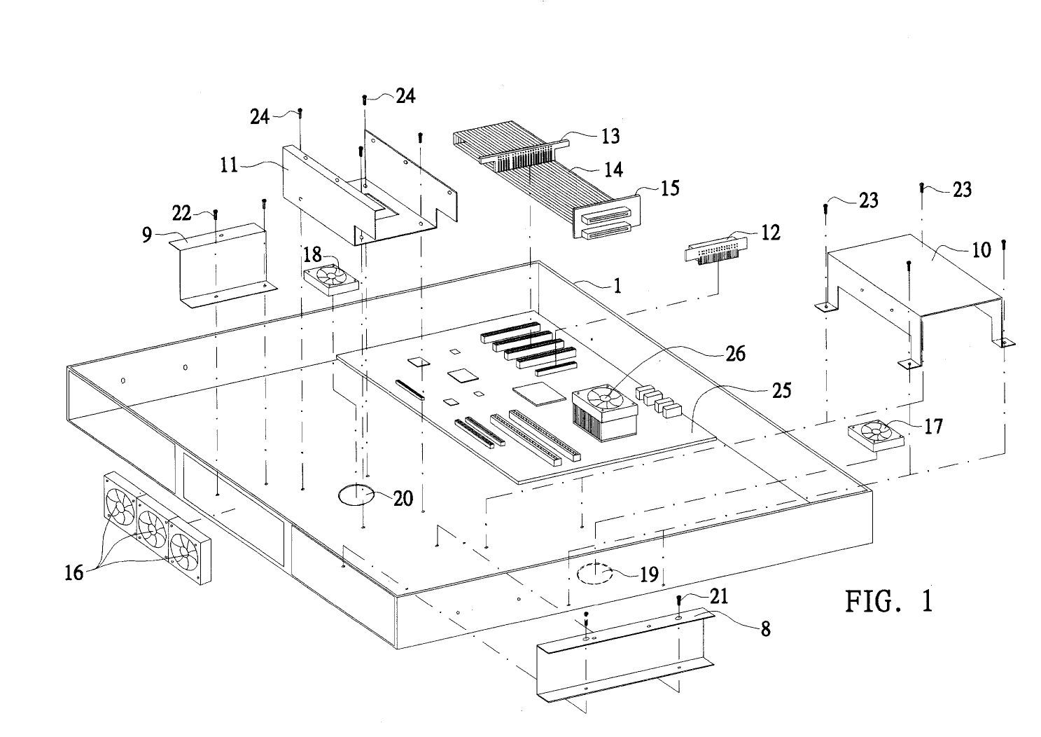

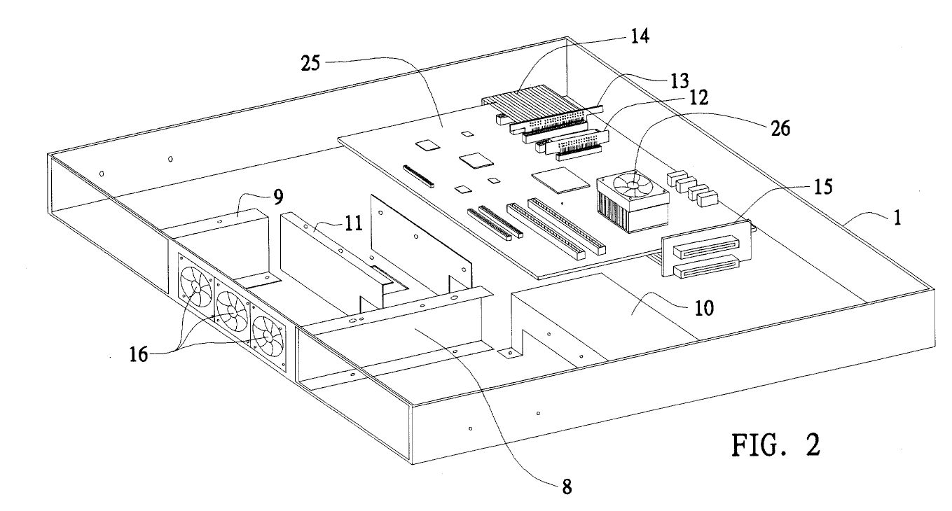

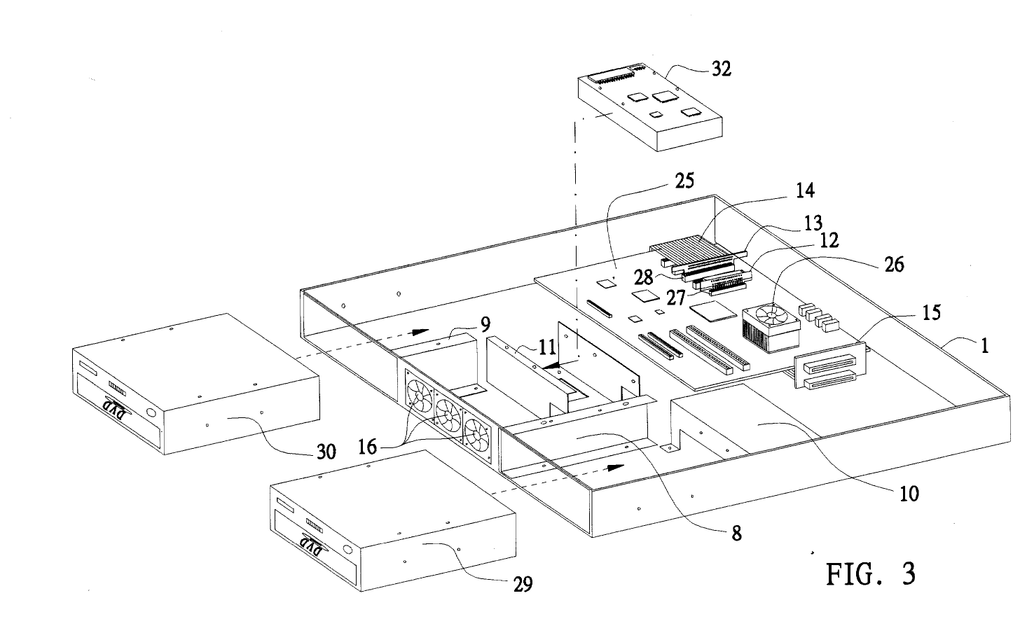

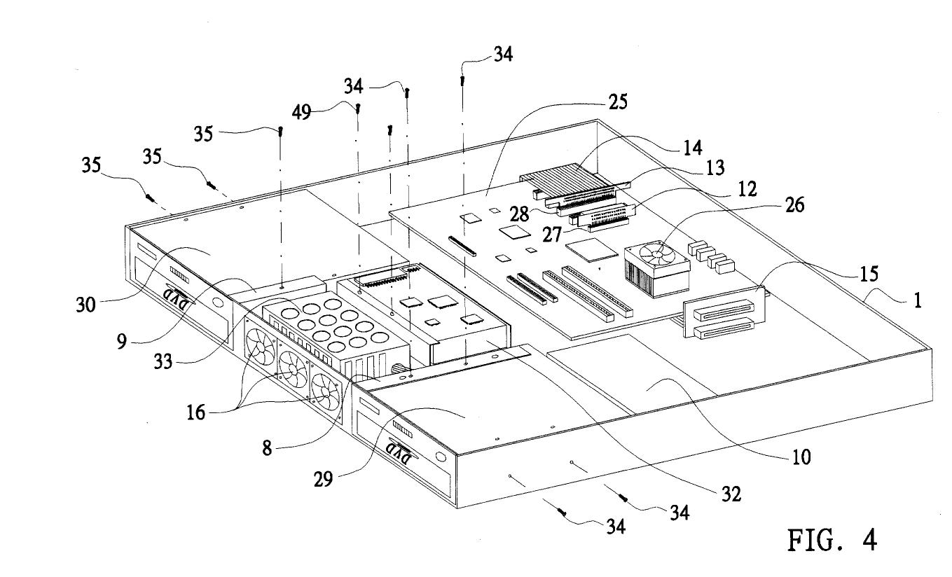

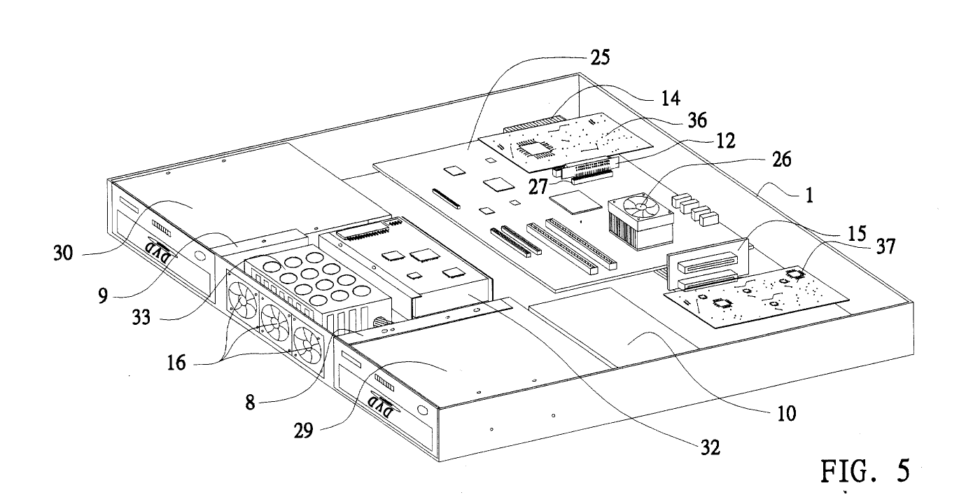

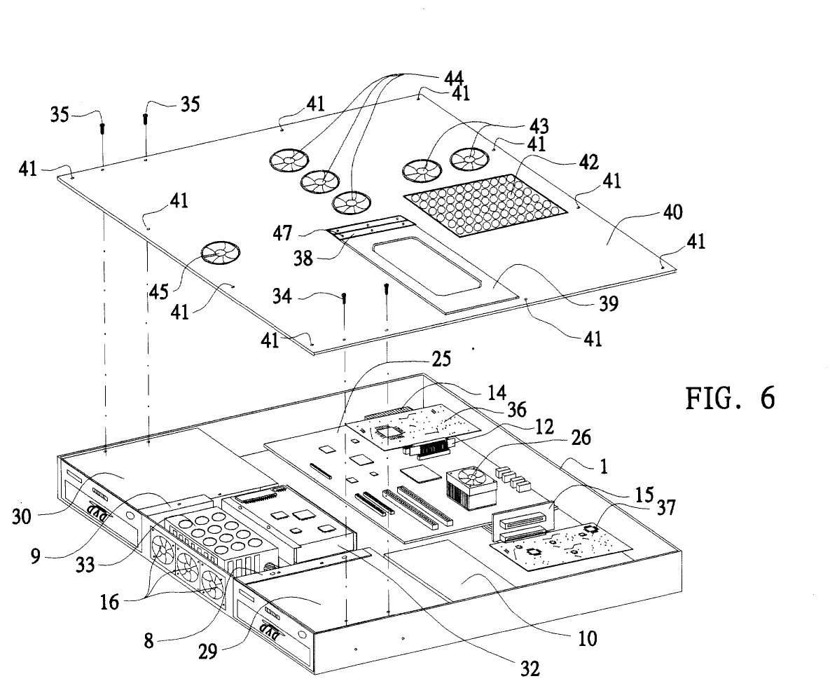

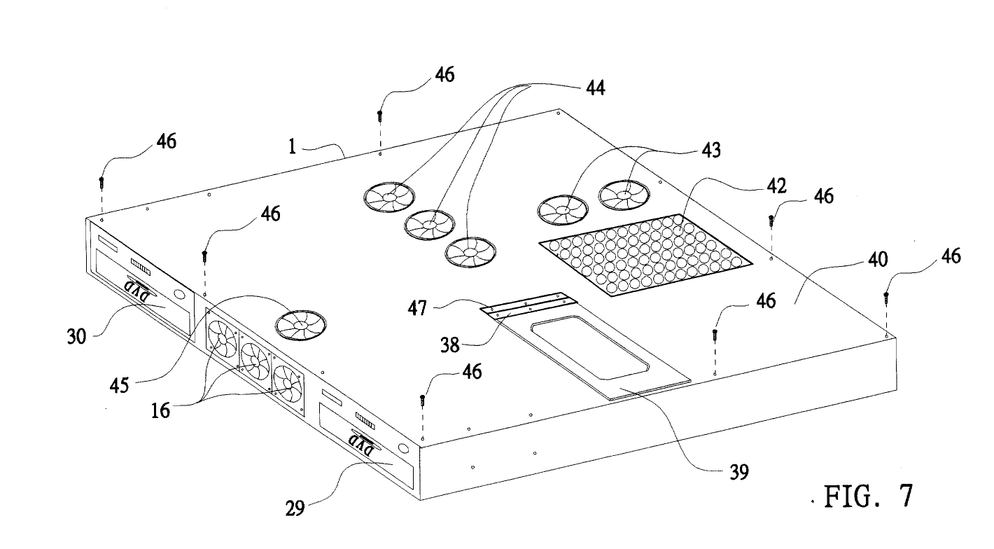

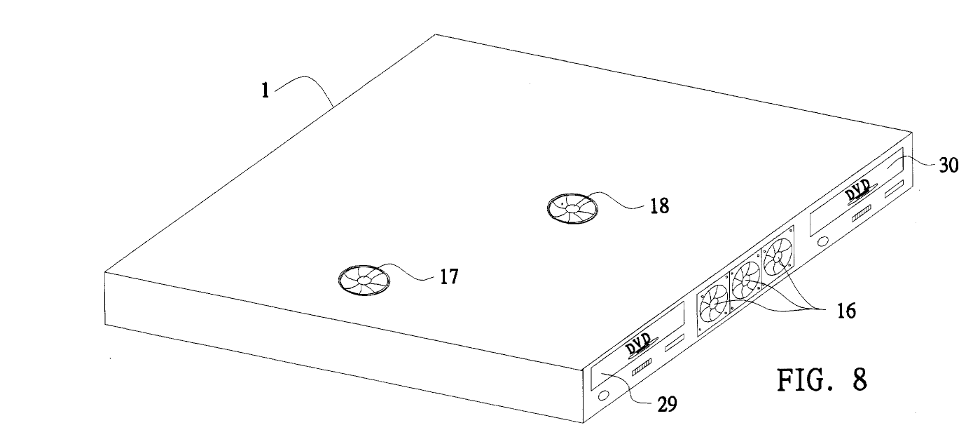

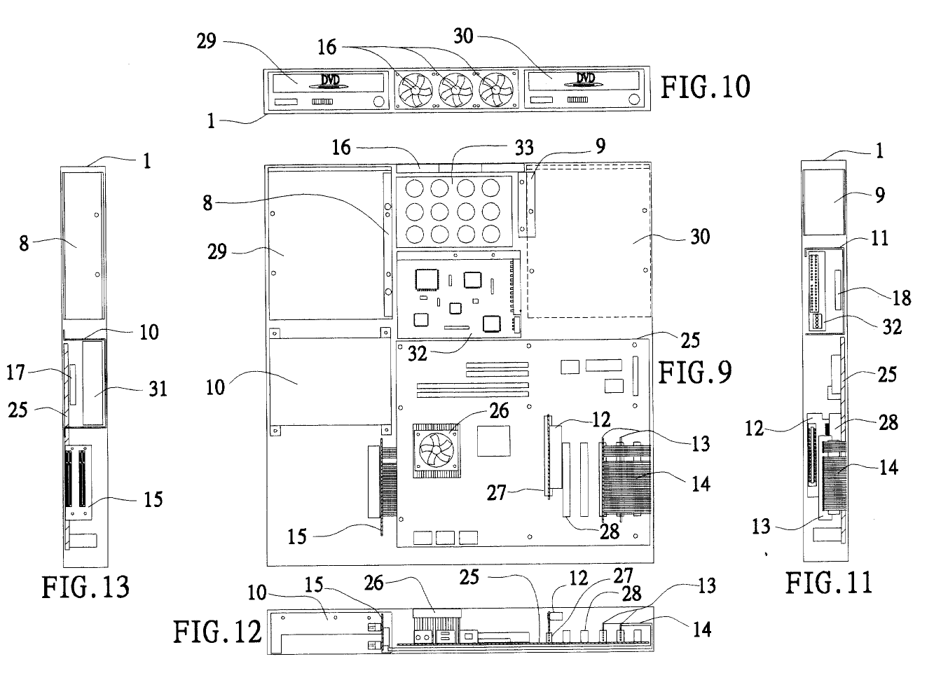

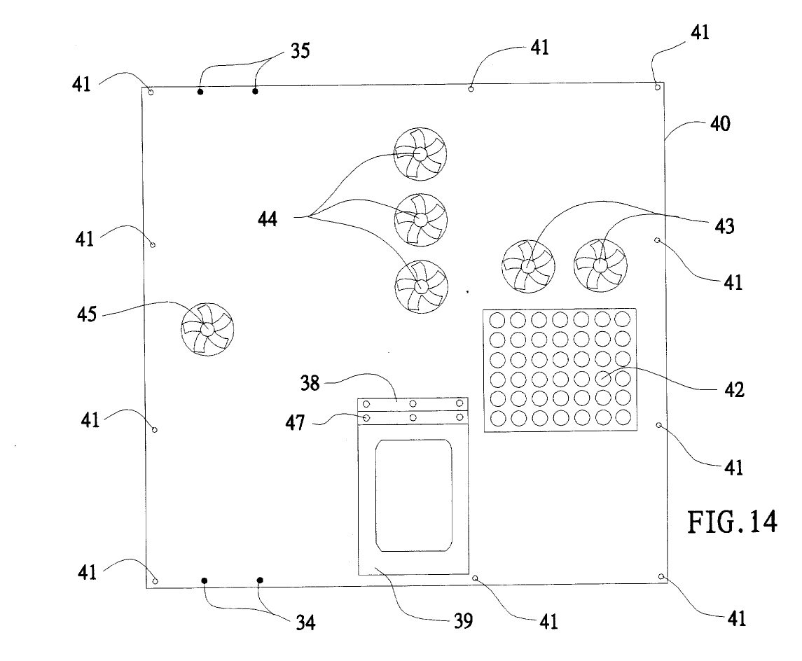

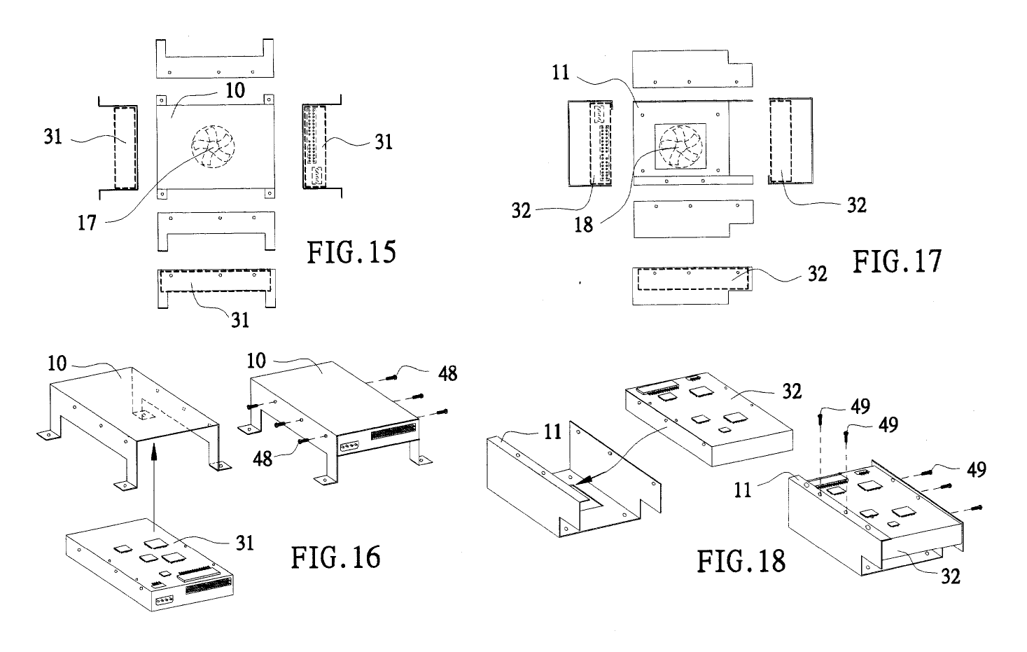

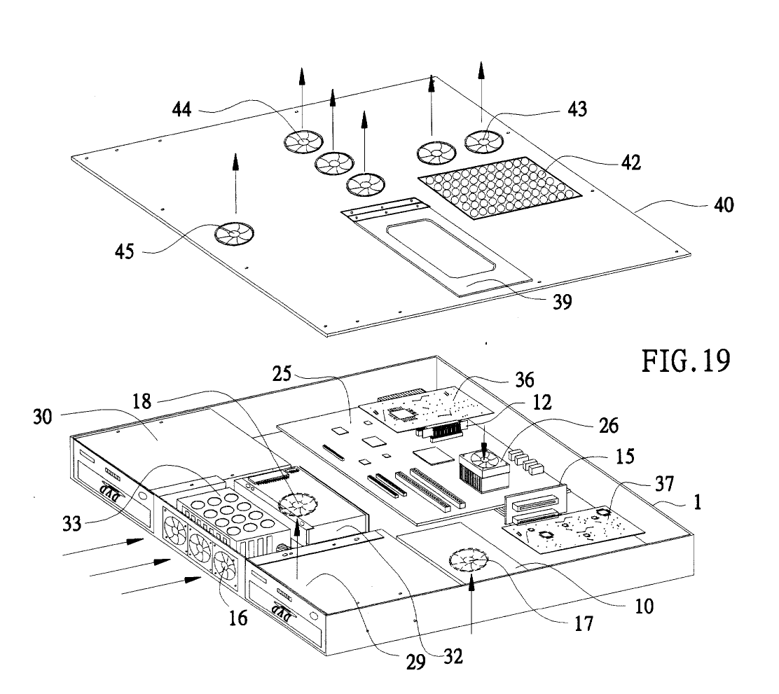

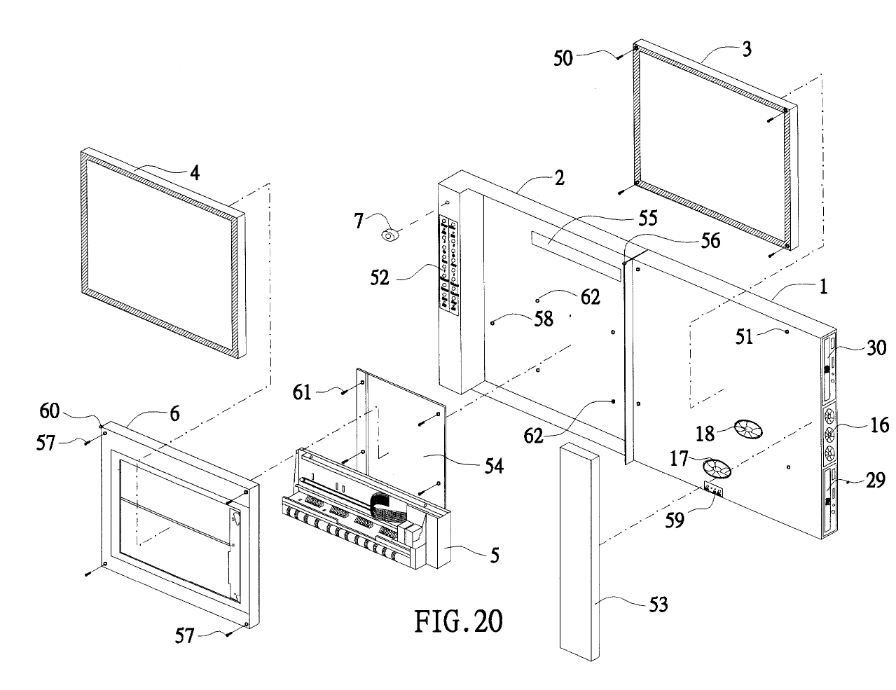

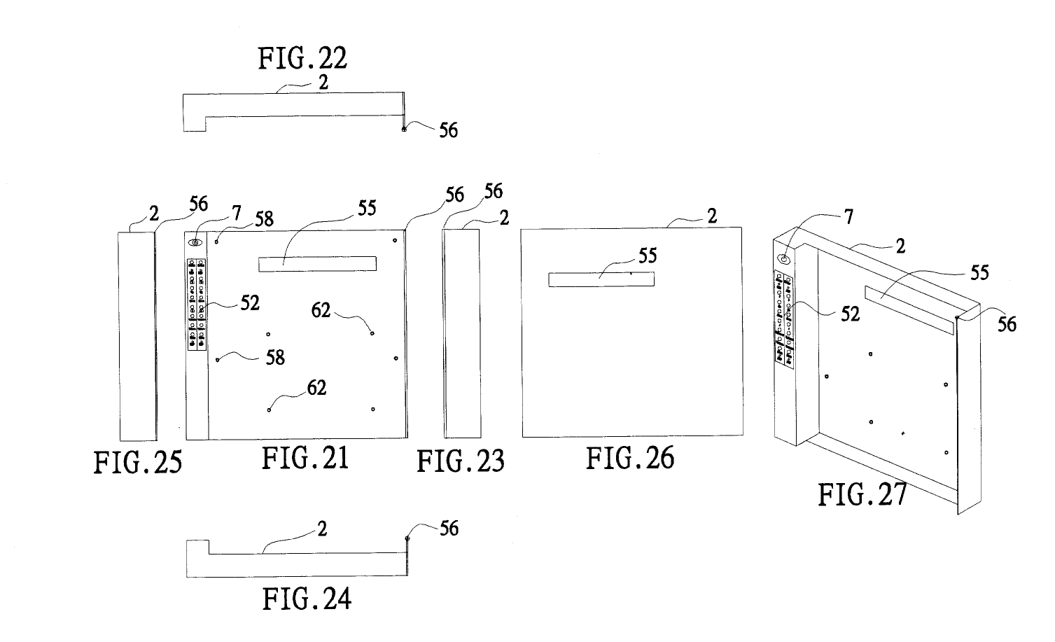

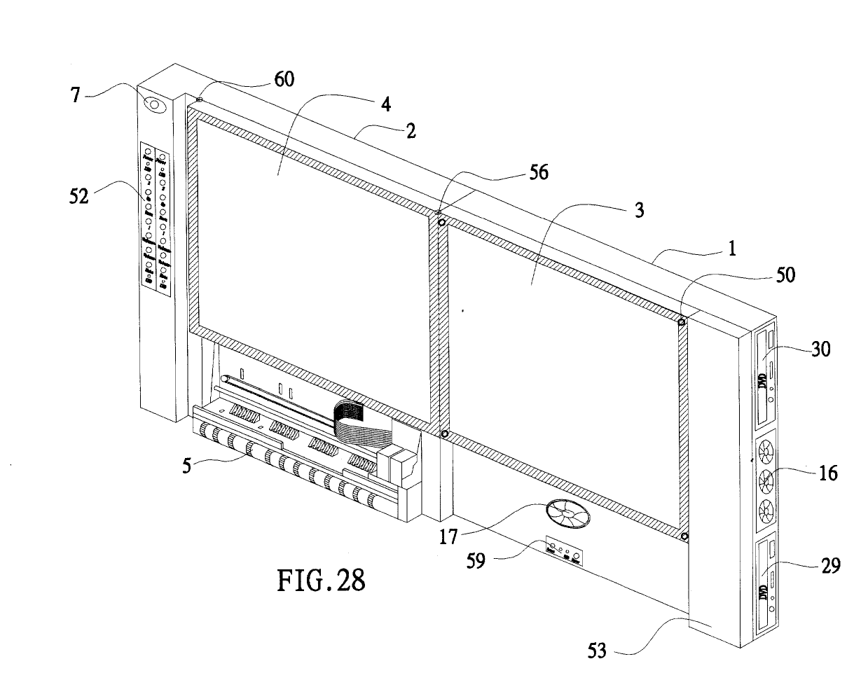

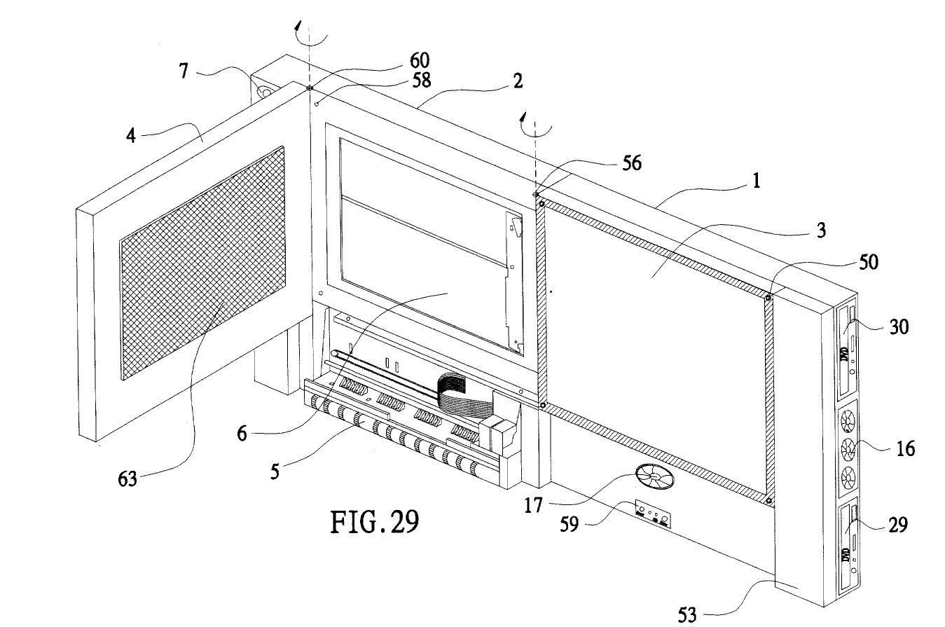

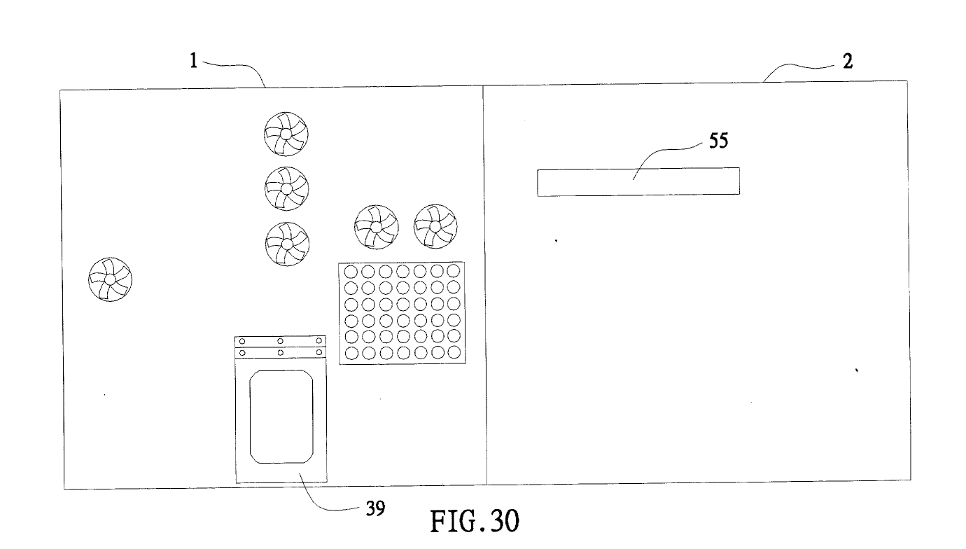

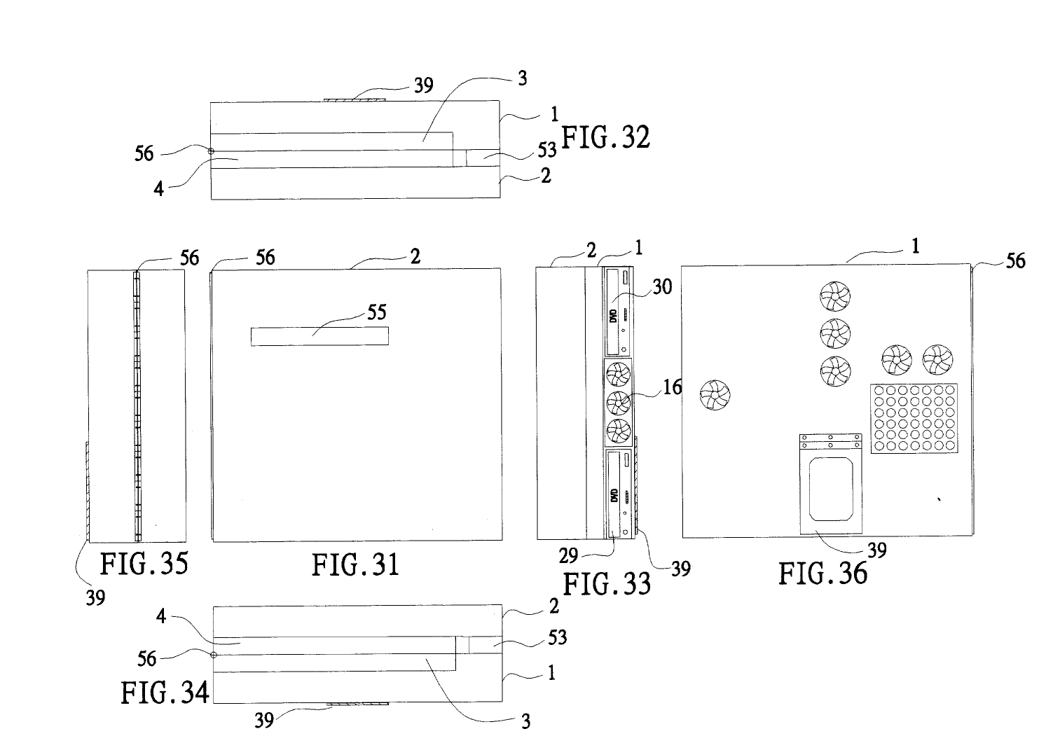

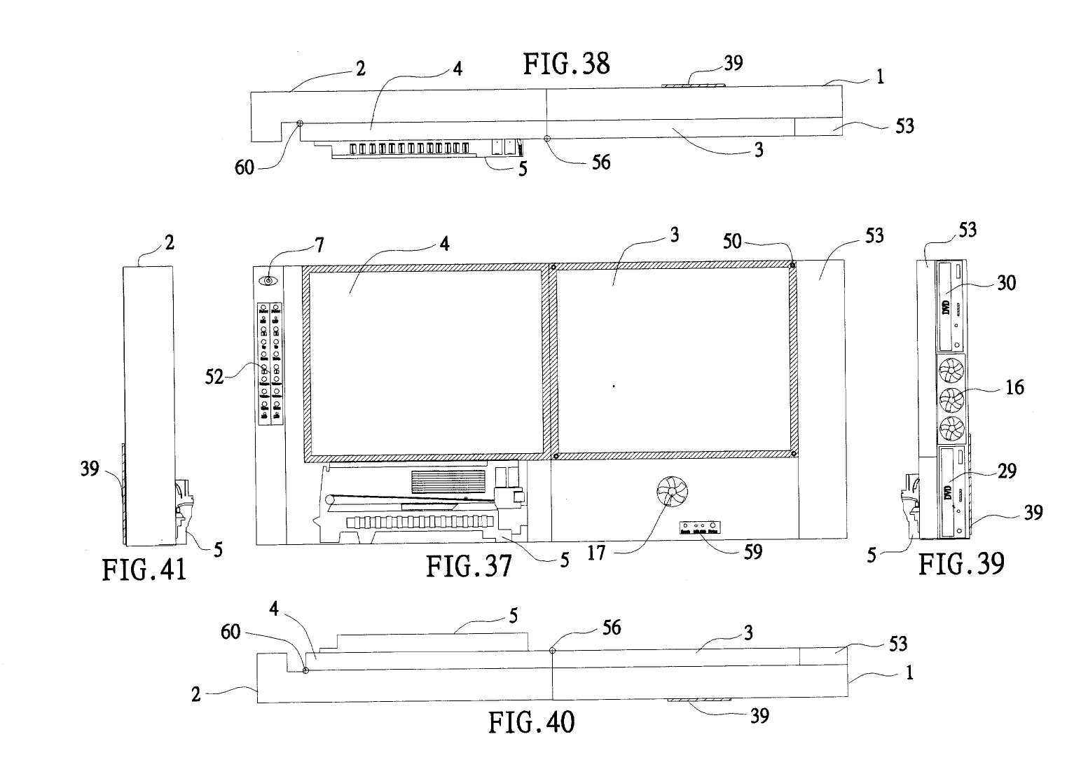

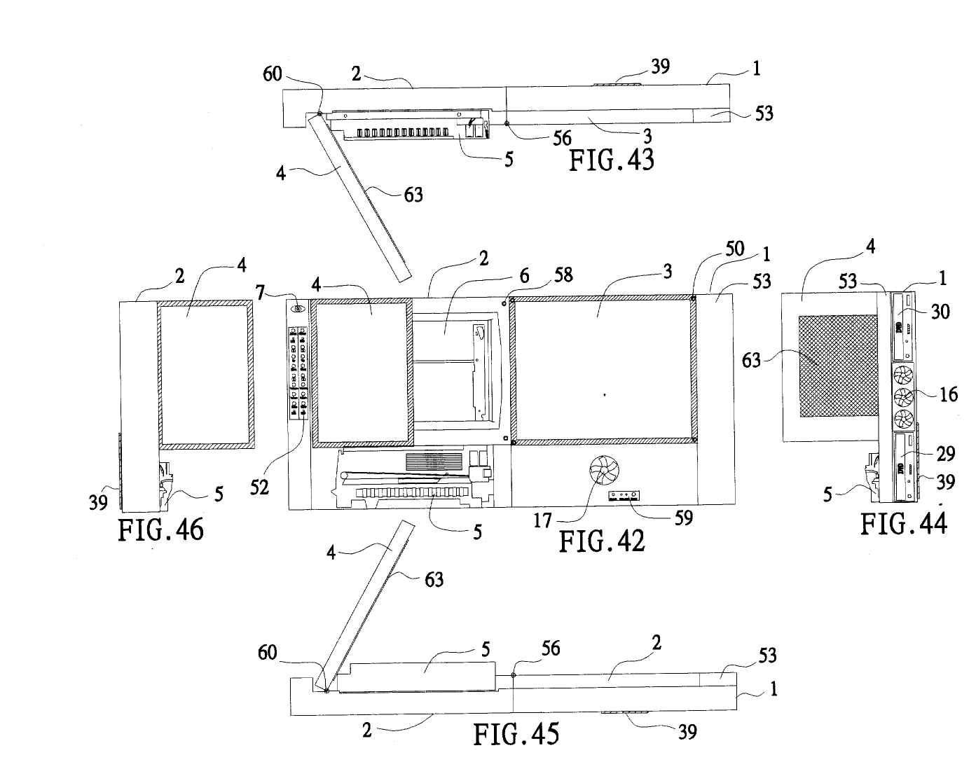

The Part List On Figures.
1 CASE A.
2 CASE B.
3 LCD monitor A.
4 LCD monitor B.
5 Printer.
6 Scanner.
7 Webcam.
8 First CD/DVD-ROM rack.
9 Second CD/DVD-ROM rack.
10 First hard disk drive rack.
11 Second hard disk drive rack.
12 AGP raise card.
13 PCI extension raise card.
14 PCI extension cable.
15 PCI extension slot.
16 Power supply inlet fans.
17 First hard disk drive inlet fan.
18 Second hard disk drive inlet fan.
19 First hard disk drive inlet hole.
20 Second hard disk drive inlet hole.
21 First CD/DVD-ROM rack mounting screw.
22 Second CD/DVD-ROM rack mounting screw.
23 First hard disk drive rack mounting screw.
24 Second hard disk drive rack mounting screw.
25 ATX form factor mainboard.
26 CPU fan.
27 Mainboard AGP slot.
28 Mainboard PCI slot.
29 First CD/DVD-ROM.
30 Second CD/DVD-ROM.
31 First hard disk drive.
32 Second hard disk drive.
33 Power supply.
34 First CD/DVD-ROM mounting screw.
35 Second CD/DVD-ROM mounting screw.
36 AGP video card.
37 PCI card.
38 Stand hinge.
39 Stand.
40 Upper panel.
41 Upper panel screw hole.
42 CPU fan inlet holes.
43 CPU heat outlet fan.
44 System heat outlet fans.
45 Power supply heat outlet fan.
46 Upper panel mounting screw.
47 Stand hinge screw hole.
48 First hard disk drive mounting screw.
49 Second hard disk drive mounting screw.
50 LCD monitor A mounting screw.
51 LCD monitor A mounting hole.
52 LCD monitor A and LCD monitor B control panel.
53 Cover.
54 Printer paper rack.
55 Printer paper feed slot.
56 CASE A and CASE B combining hinge.
57 Scanner mounting screw.
58 Scanner mounting hole.
59 Computer control panel.
60 LCD monitor B and scanner combining hinge.
61 Printer mounting screw.
62 Printer mounting hole.
63 Scanner lid.

### DETAILED DESCRIPTION

Placing the AGP raise card (part 12) and PCI extension raise card (part 13) parallel with the mainboard (part 25) reduces the size of CASE A (part 1). The PCI extension raise card (part 13) has a cable (part 14) that extends through the gap underneath the mainboard so that the cable is between the main board (part 25) and the bottom of CASE A (part 1). The cable (part 14) extension ends where the PCI slots (part 15) are beside the main board (part 25). In the design of CASE A (part 1), the first CD/DVD-ROM (part 29) and second CD/DVD-ROM (part 30) are installed reversely, or upside down. The first hard disk drive (part 31) and second hard disk drive (part 32) are also installed reversely. Therefore, when the computer is standing in a vertical position, the bottom of the computer faces you so that discs are loaded in the usual manner, rather than backwards. The first CD/DVD-ROM (part 29) and second CD/DVD-ROM (part 30) is fastened on one side by screws (part 34 and part 35) on the outside edge of CASE A (part 1), and on the opposite side by screws on the first CD/DVD-ROM rack (part 8) and second CD/DVD-ROM rack (part 9). The first hard disk drive (part 31) is fastened on the first hard disk drive rack (part 10) on the bottom of CASE A (part 1). The second hard disk drive (part 32) is enclosed between the first CD/DVD-ROM (part 29) and second CD/DVD-ROM (part 30). Also between the first CD/DVD-ROM (part 29) and second CD/DVD-ROM (part 30), located immediately in front of the second hard disk drive (part 32) is the power supply (part 33). CASE A's (part 1) cooling system is arranged as follows: there is a fan underneath the first hard disk drive (part 31) and also underneath the second hard disk drive (part 32). Both fans (part 17 and part 18) blow cold air into the first hard disk drive (part 31) and second hard disk drive (part 32). Three fans (part 16) on the edge panel blow in cold air to cool down the power supply (part 33). One fan (part 45) on the upper panel blows out the heated power supply (part 33) air. Three fans (part 44) on the upper panel, in the center, blow hot air from the system. Another set of two fans (part 43) to the side of the center fans blow out hot CPU air. Also on upper panel are a set of holes (part 42) that receives cold air for CPU. On the upper panel, there is a device similar to those on picture frames (part 39) that allows CASE A (part 1) to be propped up for convenient viewing. The device extends from the computer and acts as a stand. The dual monitors/printer/scanner/webcam all-in-one computer is arranged as followed: LCD monitor A (part 3) is screwed into CASE A (part 1). There is a printer (part 5) screwed into CASE B (part 2). A scanner (part 6) is also screwed into CASE B (part 2). There is a gap between the printer paper rack (part 54) and the back of the scanner (part 6) to hold paper for the printer (part 5). LCD monitor B (part 4) also acts as a scanner lid (part 63) for the scanner that is located directly underneath the LCD monitor B (part 4). To use the scanner, users open LCD monitor B (part 4) and vertically place a document inside. The webcam (part 7), used for visual and audio communication, is located on the top left side of CASE B (part 2). CASE A (part 1) and CASE B (part 2) are attached by a hinge (part 56), so that the entire unit may fold together for mobility or when not in use.

1. What I claim as my invention is a compact computer/printer/scanner/webcam all-in-one unit with dual LCD monitors. This all-in-one computer has two major parts: CASE A and CASE B. CASE A includes a first hard disk drive rack, a second hard disk drive rack, a first CD/DVD-ROM rack, a second CD/DVD-ROM rack, a first hard disk drive fan inlet hole, a second hard disk drive fan inlet hole, a first hard disk drive fan, a second hard disk drive fan, a stand, a power supply heat outlet fan, CPU fan inlet holes, two PCI extension raise card/PCI extension cable/PCI extension slot, two CPU heat outlet fans, three power supply inlet fans and three system heat outlet fans. CASE A contains one LCD monitor. The CASE A cooling system is arranged as follows: There is a fan underneath the first hard disk drive and also underneath the second hard disk drive. Both fans blow cold air into the first and second hard disk drive. Three fans on the edge panel blow in cold air to cool down the power supply. A fan on the upper panel blows out the heated power supply. Three fans on the upper panel in the center, blow hot air from the system. Another set of two fans to the side of the center fans blow out hot CPU air. Also on upper panel are a set of holes that receives cold air for CPU. CASE B includes a printer, a scanner, a webcam, a LCD monitor.

2. What I claim as my invention is: A gadget according to claim 1, further comprising CASE A.

3. What I claim as my invention is: A gadget according to claim 1, further comprising CASE B.

5. What I claim as my invention is: A gadget according to claim 1, further comprising a second hard disk drive rack.

6. What I claim as my invention is: A gadget according to claim 1, further comprising a first CD/DVD-ROM rack.

7. What I claim as my invention is: A gadget according to claim 1, further comprising a second CD/DVD-ROM rack.

8. What I claim as my invention is: A gadget according to claim 1, further comprising two PCI extension raise card/PCI extension cable/PCI extension slot.

9. What I claim as my invention is: A gadget according to claim 1, further comprising two hard disk drive fans, two hard disk drive fan inlet holes, three power supply inlet fans, a power supply heat outlet fan, CPU fan inlet holes, two CPU heat outlet fans, three power supply inlet fans and three system heat outlet fans.

10. What I claim as my invention is: A gadget according to claim 1, further comprising a printer set in CASE B.

11. What I claim as my invention is: A gadget according to claim 1, further comprising a scanner set in CASE B.

12. What I claim as my invention is: A gadget according to claim 1, further comprising a webcam set in CASE B.

13. What I claim as my invention is: A gadget according to claim 1, the arrangement of all parts in CASE A.

14. What I claim as my invention is: A gadget according to claim 1, the arrangement of all parts in CASE B.

15. What I claim as my invention is: A gadget according to claim 1, further comprising of the combination of CASE A and CASE B into an all-in-one computer/dual LCD monitors/printer/scanner/webcam unit.
